(19) United States
(12) Patent Application Publication
(10) Pub. No.: US 2009/0102408 A1
(43) Pub. Date: Apr. 23, 2009

(54) BACKWARD PEDALING DETECTION CIRCUIT FOR E-BIKE MOTOR DRIVER

(75) Inventors: Allan Candelaria DE JESUS, Singapore (SG); Yubin LIU, Singapore (SG); Tien Yew KANG, Singapore (SG); Kian Teck TEO, Singapore (SG)

Correspondence Address: GREENBLUM & BERNSTEIN, P.L.C., 1950 ROLAND CLARKE PLACE, RESTON, VA, 20191, US

(73) Assignees: MATSUSHITA ELECTRIC INDUSTRIAL CO., LTD., Osaka (JP); PANASONIC SEMICONDUCTOR ASIA PTE., LTD., Singapore (SG)

(21) Appl. No.: 11/874,425

(22) Filed: Oct. 18, 2007

(51) Int. Cl. H02P 3/06; B62M 23/02; G01R 29/027

(52) U.S. Cl. 318/466; 318/450; 180/206; 327/37; 318/484

(57) ABSTRACT

A backward pedaling detection circuit has a charging/discharging circuit for charging and discharging the external capacitor to meet the threshold voltage required by the hysteresis comparator, based on the input from the hall sensor. An internal pull-down circuit, based on the pedal speed, keeps the circuit from false triggering. A comparator with hysteresis (Schmitt trigger) sets the upper and lower threshold voltage and eliminates the effect of noise. AND gates act like switches to allow the selected signal to pass through.

### BACKGROUND OF THE INVENTION

The current invention relates to in general, a motor driver controller with a pedal assist function for electric bicycles and more particularly, to circuits and methods for detection of backward pedaling movements and prevention of motion of the electric bicycle during such movements.

Electric bicycles are typically powered by motors and the user determines the speed at which the motor drives his electric bicycle through either:

a. the throttle control, or

b. pedal-assist function.

As this invention relates more to the pedal-assist function, hence, further elaboration of the pedal-assist function shall be described, and not the throttle control. As disclosed in Provisional Patent Application U.S. 60/886,413 (“Motor Driver Controller for Electric Bicycle”), an operation of such a pedal assist function is described. FIG. 1 shows the block diagram showing the pedal-assist function system of the prior art.

Referring to FIG. 1, pedals of electric bicycle are equipped with Hall sensors. Suppose the pedal is continuously monitored by Hall sensors, it is possible to track the pedal's position information, and hence its speed information. These Hall sensors subsequently output a signal containing the speed information. Because of the rotational nature of pedal, the output signal from Hall sensor is a series of pulses. The output signal from the Hall sensors is applied to speed counter 29. Speed counter 29 counts time between two consecutive pulses from the Hall sensor, such as between two consecutive Hall sensor signal rising edges. Speed counter 29 may be so arranged to count the number of pulses per a unit time. Thus, the speed counter 29 detects the rotational speed of pedal. The counter output 30 is such that, per a unit time, the faster the pedal is stepped, the greater the count is. Thus, per a unit time, the counted result of a high value corresponds to a fast pedal speed, and a low value corresponds to a slow pedal speed.

According to the pedal speed counter 29, decoder 31 decides which assisting level to provide. If the pedal is being stepped fast, higher assisting power is provided. Conversely, the slower the pedal is being stepped, lower assisting power is provided. Through a pedal assist select block 15, only PWM signal generated from the pedal assist block 35 is fed to drive the motor.

However, the limitation of this pedal-assist function is that the PWM signal generated from Comparator 34 will still be fed to the motor driver regardless of direction of pedaling, that is, whether forward or backward. This means, the electric bicycle under the pedal-assist mode will still move forward even if the user pedals in the backward direction. This poses a danger, as an unsuspecting rider may not anticipate such a reaction from the electric bicycle and may thus result in the rider falling off his vehicle. Another problem with the prior art is that if the backward pedaling occurs when the bicycle is stationary, there will be a sudden increase in current across the Motor Driver Bridge 19, and if the surge is large enough, may cause it to be damaged.

It is intended for the present invention to solve those problems mentioned. For the present invention, a backward pedaling detection circuit capable of detecting input signal with varying duty cycles from a pulse type hall sensor fixed at the pedal is disclosed.

The present invention makes use of the operating knowledge of pulse type hall sensors commonly used in the electric bicycle industry. An example of such is the WSY02 module manufactured by the Suzhou Bafang Electric Motor Science-Technology Co., Ltd of China. This module provides a pulse type hall sensor assembly that is able to generate pulse signals based on the direction of rotation of the sensors. For a forward direction, the fixed pulse width generated will have a duty cycle of less than 45%. For a reverse direction, the fixed pulse width generated will have a duty cycle of more than 55%.

The present invention is basically a protection circuit which can recognize that forward pedal movements produce a pulse signal with high duty cycle and backward pedal movement produce a pulse signal with low duty cycle. The present invention hence protects the motor driver from activation when the pedal is moved backward.

### SUMMARY OF THE INVENTION

An object of this invention is to implement an analog type backward pedaling detection circuit which can effectively detect and differentiate input pulses with high and low duty cycles. This will thus provide protection for the motor driver with pedal assist function.

According to the present invention, said backward pedaling detection circuit comprises: a charging/discharging circuit with an external capacitor to adjust timing, a hysteresis comparator to set the threshold and logic ‘AND’ gates to collectively act like a switch.

### BRIEF DESCRIPTION OF THE DRAWINGS

FIG. 1 is a block diagram showing a prior art of the pedal-assist function;

FIG. 2 is a block diagram showing one example of a backward pedaling detection circuit according to first invention;

FIG. 3 is a block diagram showing another example of a backward pedaling detection circuit according to first invention;

FIG. 4 is a diagram showing the relationship among input and output voltages.

FIGS. 5A, 5B, 5C and 5D are diagrams showing arrangements of the Hall sensor with respect to the pedal.

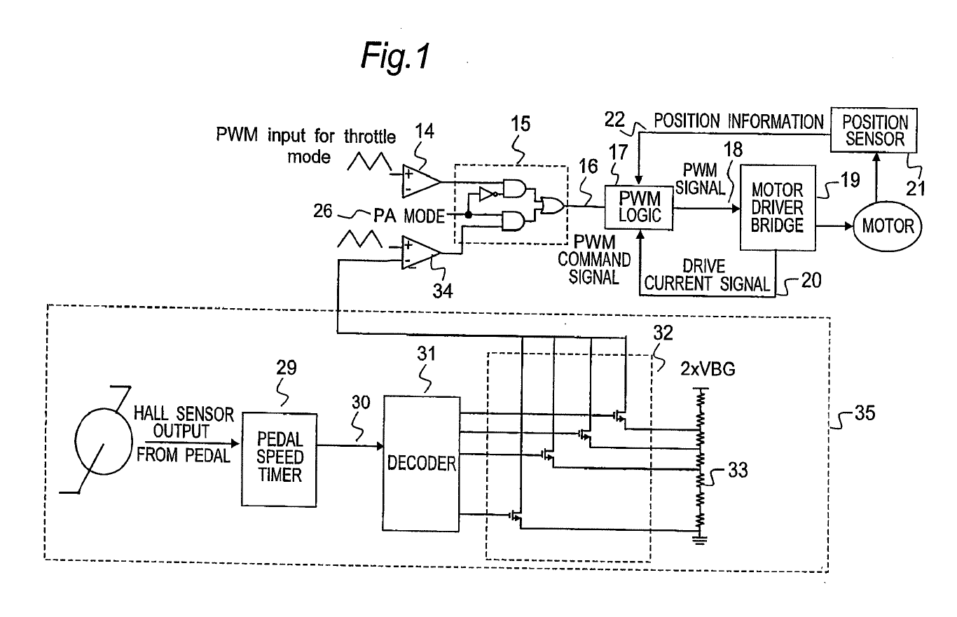

### DETAILED DESCRIPTION OF THE PREFERRED EMBODIMENT

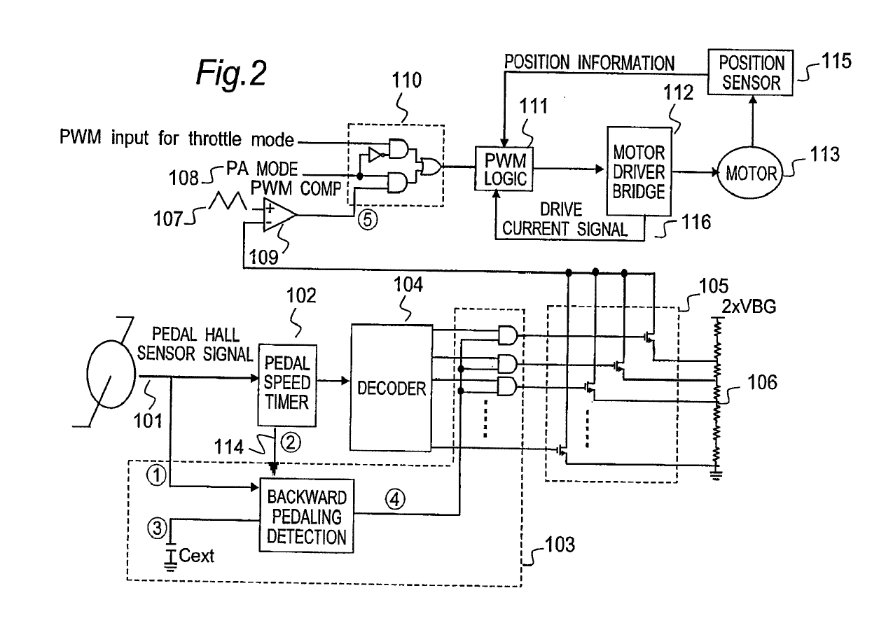

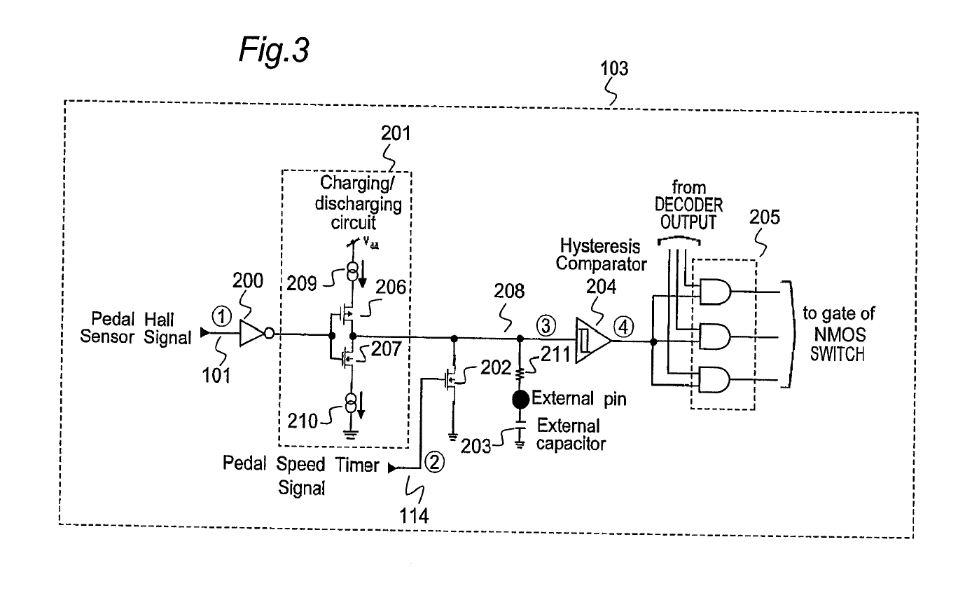

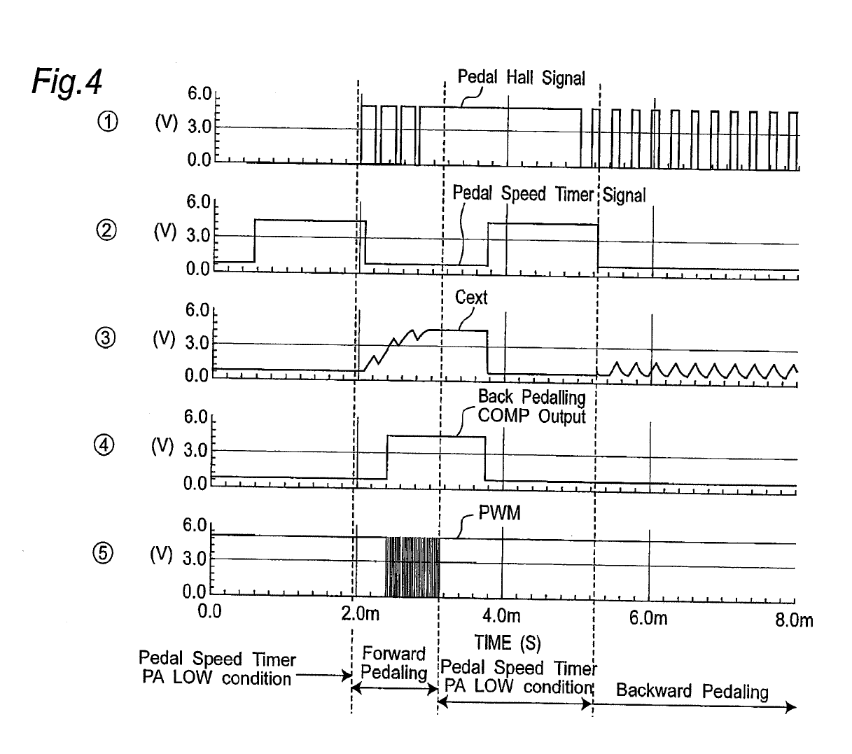

FIG. 2 shows one example of a backward pedaling detection circuit 3 introduced to a pedal-assist function system according to the present invention. In FIGS. 2 and 3 the reference numbers shown in circles correspond to waveforms shown in FIG. 4.

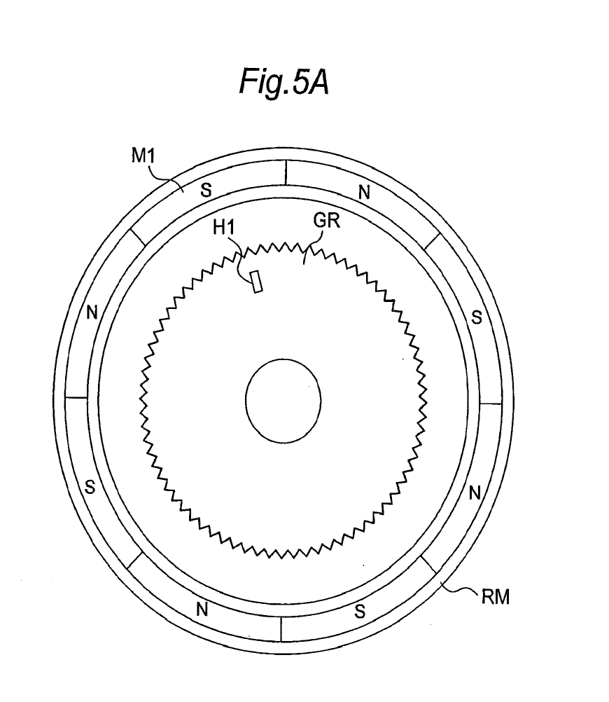

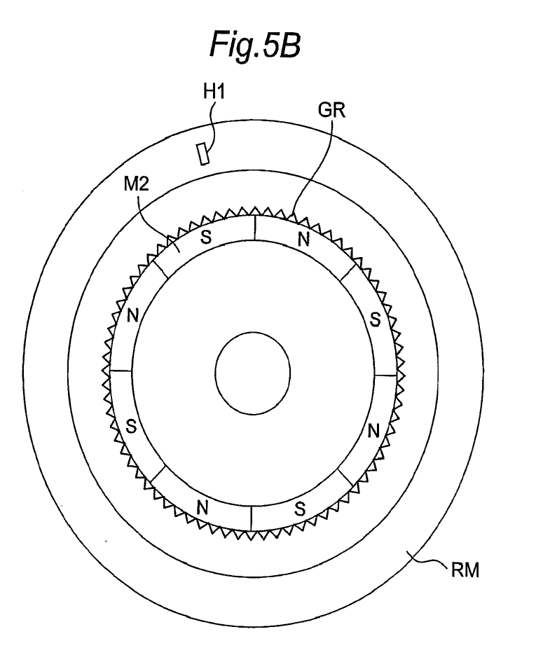

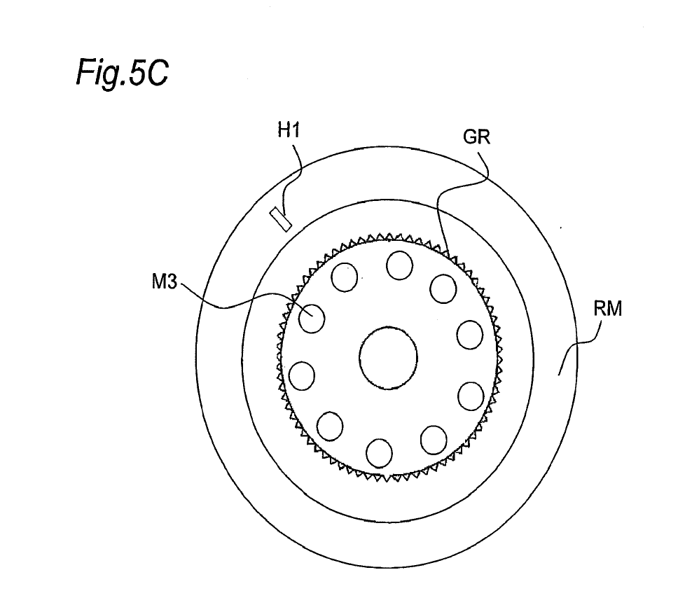

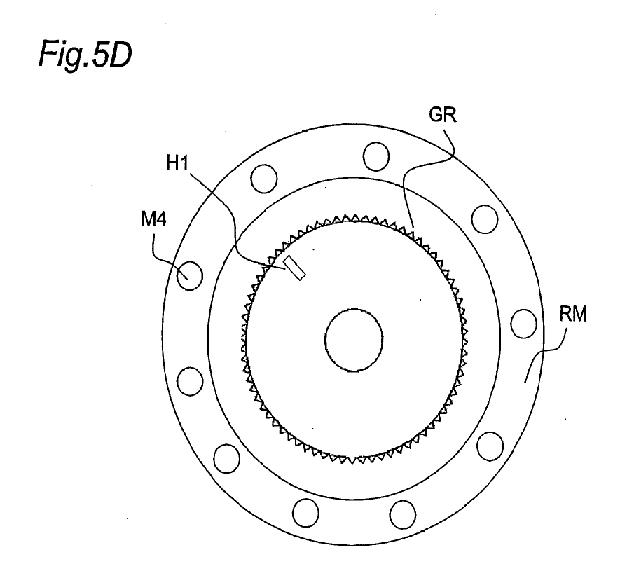

Referring to FIG. 5A, one example of arrangement of the pulse type hall sensor with respect to the pedal is shown. The pedal is firmly connected to a gear or a chain-ring GR. Provided around the gear GR is the frame RM. The gear GR is provided with Hall sensor H1 as shown. Provided on the frame RM are permanent magnets M1 so that four N poles and four S poles appear alternately at equal spaced angle of 45 degrees. As the gear GR rotates, the Hall sensor H1 detects the magnetic field change, resulting in producing of pulses, or sinusoidal signal. By one revolution or rotation of the gear GR the Hall sensor H1, produces a signal of four cycles. Modifications of arrangement for providing Hall sensors are shown in FIGS. 5B, 5C and 5D. The number of pairs of N pole and S pole can be any number from one.

Referring to FIG. 5B, Hall sensor H1 is provided on the frame as shown. Provided on the gear GR are permanent magnets M1 so that four N poles and four S poles appear alternately at equal spaced angle of 45 degrees.

Referring to FIG. 5C, yet another example of arrangement of the pulse type hall sensor with respect to the pedal is shown. The pedal is firmly connected to a gear or a chain-ring GR. Provided around the gear GR is the frame RM. The frame is provided with Hall sensor H1 as shown. Provided on the gear GR are disc-like permanent magnets M3 that are arranged so that 10 magnets of the same polarity, either all N poles or all S poles, are spaced out equidistant to each other. As the gear GR rotates, the Hall sensor H1 detects the magnetic field change, resulting in producing of pulses, or sinusoidal signal. By one revolution or rotation of the gear GR the Hall sensor H1, produces 10 pulses. Modification of arrangement for providing Hall sensors is shown in FIG. 5B. The number of permanent magnets can be any number from 2.

Referring to FIG. 5D, Hall sensor H1 is provided on the gear GR as shown. Provided on the frame RM are disc-like permanent magnets M3 that are arranged so that 10 magnets of the same polarity, either all N poles or all S poles, are spaced out equidistant to each other.

FIG. 2 shows an application of the preferred embodiment of the current invention and the connections in relation to a typical pedal assist function system. FIG. 3 shows an example of Backward Pedaling Detection Circuit 103 according to the present invention. The input of inverter 200 is connected to the pedal hall sensor signal output 101. The output of the inverter 200 is connected to the gate terminals of PMOS 206 and NMOS 207. The source terminal of PMOS 206 is connected to a current source 209 powered from a Vdd power supply. The source terminal of NMOS 207 is connected to a current source 210 which sinks current to ground. The combination of NMOS 207, PMOS 206 and current sources 209 and 210 is collectively called the Charging/Discharging circuit 201. The drain terminals of PMOS 206 and NMOS 207 are connected to the drain terminal of NMOS 202 via node 208. The gate terminal of NMOS 202 is connected to the pedal speed timer signal 114, whereas its source terminal is connected to ground. Node 208 also connects to the external capacitor 203 via resistor 211. The other terminal of external capacitor 203 is grounded. The input of the hysteresis comparator 204 is connected to node 208. The output of hysteresis comparator 204 is connected to one of the inputs of AND gates 205. The other inputs of AND gates 205 are connected to the Decoder 104 outputs. The AND gates' 205 outputs are connected to the gate terminals of the NMOS switches 105.

Next, the operation of such an arrangement is described below.

The Hall Sensor output signal 101 will be fed to Backward Pedaling Detection circuit 103 and to Pedal Speed Timer block 102. Initially, when there is no signal from pedal hall sensor, it is said to be on PA (pedal assist) Low condition which means that the output of the Backward Pedaling Detection circuit 103 is default to LOW. This is because of the following reason: The Pedal Speed Timer block 102, which consists of counters, will give a HIGH signal at output 114, for a case of no pedaling detected. This will turn ON, transistor 202 (FIG. 3), thus forcing the input and output of the hysteresis comparator 204 to be LOW.

As mentioned, pulse type hall sensors are used. For these sensors, for a motion in the backward direction, a signal with a duty cycle of less than 45 percent is outputted. When this occurs, the backward pedaling detection circuit 103 will output a LOW signal voltage. This means that it will not allow any signal coming from the DECODER 104 to activate any of the NMOS switches 105.

When none of the NMOS switches 105 is turned ON, the PWM COMP 109 inverting input is low and is below the threshold of the triangular signal 107. The PWM COMP 109 output is always on HIGH state. The output of the Pedal Assist Mode Select Block 110 will thus become HIGH which will not cause any switching to PWM LOGIC 111 and will not drive the MOTOR DRIVER BRIDGE 112 and will result in no commutation from the motor 113.

For the case when the rider suddenly pedals in the backward direction after pedaling in the forward direction initially, the following operation occurs: As mentioned, the Pedal Hall Sensor Signal 101 will give a signal with a duty cycle of less than 45 percent. The inverter 200 inverts the signal and thus causes NMOS 207 to be ON, and PMOS 206 to be OFF for most of the duty cycle. Meanwhile, since pedaling motion is detected, the Pedal Speed Timer Signal 114 will be LOW, thus NMOS 202 will be off. This results in the charges from External Capacitor 203 to be discharged via NMOS 207. The corresponding waveform of the External Capacitor 203 (node 208) is as shown in FIG. 4. Hence, with node 208 being pulled to a LOW level, it will be lower than the pre-determined lower threshold of the Hysteresis Comparator 204. The pre-determined lower threshold is made slightly higher than the node 208 voltage level under a reverse pedaling situation. As a result, the Hysteresis Comparator 204 will output a LOW signal and hence disabling the AND gates array 205 output. This means that it will not allow any signal coming from the DECODER 104 to activate any of the NMOS switches 105.

The operation of the invention for the case of a forward pedaling is described as follows: For these Pulse Type Hall Sensors, for a motion in the forward direction, a signal with a duty cycle of more than 55 percent is outputted. Hence, when the duty of the hall signal from the Pedal Sensor 101 is more than 55 percent, the inverter 200 inverts the signal and thus causes PMOS 206 to be ON, and NMOS 207 to be OFF for most of the duty cycle. Meanwhile, since pedaling motion is detected, the Pedal Speed Timer Signal 114 will be LOW, thus NMOS 202 will be off. This results in the charging up of the External Capacitor 203 via PMOS 206. The corresponding waveform of the External Capacitor 203 (node 208) is as shown in FIG. 4. Hence, with node 208 being pulled to a HIGH level, it will be higher than the pre-determined higher threshold of the Hysteresis Comparator 204. The pre-determined higher threshold is made slightly lower than the node 208 voltage level under a forward pedaling situation. As a result, the Hysteresis Comparator 204 will output a HIGH signal and hence enabling the AND gates array 205 output. This means that it will allow any signal coming from the DECODER 104 to activate the corresponding NMOS switches 105. DECODER 104 will thus turn ON and select any of the NMOS switches 105 based on the signal coming from PEDAL SPEED TIMER 102.

When one of the NMOS switches 105 is turned ON, the PWM COMP 109 inverting input is equal to the voltage set by the resistor tree 106. The DECODER 104 will determine which voltage level to set to by turning on the corresponding NMOS switch 105. This voltage will be compared to a triangular signal 107 to determine the duty cycle of the PWM COMP 109 output. The Pedal Assist Mode Select Block 110 output follows the PWM COMP 109 output signal. The switching signal will be processed by the PWM LOGIC 111 and then drive the MOTOR DRIVER BRIDGE 112 that will result in commutation from the MOTOR 113.

The Position Sensor 115 and the Drive Current Signal 116 serve as information feedback for the PWM logic to ensure that the desired Motor speed is achieved.

What is claimed is:

1. A backward pedaling detection circuit comprising:
a charging/discharging circuit operable to charge and discharge the external capacitor to meet the threshold voltage required by the hysteresis comparator, based on the input from the hall sensor;
an internal pull-down circuit operable based on the pedal speed to keep the circuit from false triggering;
a comparator with hysteresis (Schmitt trigger) to set the upper and lower threshold voltage and eliminate the effect of noise;
AND gates to act like switches, to allow the selected signal to pass through.

2. A backward pedaling detection circuit according to claim 1,
Wherein the higher threshold of the hysteresis comparator is determined by the expected DC level achievable when the external capacitor is charged by a pulse with a duty cycle of more than 55%;
And the lower threshold of the hysteresis comparator is determined by the expected DC level achievable when the external capacitor is charged by a pulse with a duty cycle of less than 45%.

3. A method for the backward pedaling detection circuit to detect high and low duty cycle, the method comprising:
using a charging/discharging circuit operable to charge and discharge the external capacitor to meet the threshold voltage required by the hysteresis comparator;
using an internal pull-down operable based on the pedal speed to protect the circuit from false triggering due to initial condition of the hall sensor signal;
using a comparator with hysteresis (Schmitt trigger) to set the upper and lower threshold voltage and eliminate the effect of noise;
selecting of signals to pass through using AND gates.

4. A method for the backward pedaling detection circuit to set the percentage threshold for high and low duty cycle, the method comprising:
setting the high duty cycle is set to more than 55 percent and the low duty cycle is set to below 45 percent. The ratio can be adjusted by setting the threshold of the hysteresis comparator, the charging and discharging current and the value of the external capacitor.

5. A method for changing the pedal assist activation timing, the method comprising:
setting externally by changing the capacitor value.
